(19) United States
(12) Patent Application Publication
(10) Pub. No.: US 2016/0053364 A1
(43) Pub. Date: Feb. 25, 2016

(54) ARC VAPORIZATION OF METALLIC, INTERMETALLIC, AND CERAMIC TARGET MATERIALS IN ORDER TO PRODUCE Al-Cr-N COATINGS

(71) Applicant: OERLIKON TRADING AG, TRUBBACH, Trubbach (CH)

(72) Inventors: Corinna Sabitzer, Launsdorf (AT); Joerg Paulitsch, Loeben (AT); Peter Polcik, Reutte (AT); Paul Heinz Mayrhofer, Neckenmarkt (AT); Mirijam Arndt, Bad Ragaz (CH); Richard Rachbauer, Feldkirch (AT)

(73) Assignee: Oerlikon Surface Solutions AG, Trubbach, Trubbach (CH)

(21) Appl. No.: 14/785,357

(22) PCT Filed: Apr. 14, 2014
(86) PCT No.: PCT/EP2014/000989

§ 371 Date: Oct. 19, 2015

(30) Foreign Application Priority Data
Apr. 18, 2013 (DE) 10 2013 006 633.6

(51) Int. Cl. C23C 14/32; C23C 14/06

(52) U.S. Cl. CPC C23C 14/325; C23C 14/0641

(57) ABSTRACT

Arc vaporization of targets produced by means of powder metallurgy in Which the components are in the form of intermetallic compounds. The target is produced using a powder that contains a first and second intermetaallic compound and/or a first and second ceramic compound.

### FIELD OF THE INVENTION

The present invention relates to a coating method based on cathodic arc vaporization.

### BACKGROUND OF THE INVENTION

Cathodic arc vaporization is a known method for depositing nitrides such as AlₓCr₁₋ₓN layers at high coating rates. This method can be used to produce coatings that are dense and adhere well to the surface. But during the coating process, macro-particles (droplets) form, which become incorporated into the layers and impair the layer quality. Droplet formation occurs particularly when a target contains at least two metals that have very different melting points, as is the case with aluminum and chromium. In this connection, the size and number of these droplets can be reduced by increasing the flow of nitrogen.

The object of the present invention, however, is to further reduce the number and size of the droplets.

### SUMMARY OF THE INVENTION

According to the invention, the arc vaporization is operated using targets produced by means of powder metallurgy in which the components are in the form of intermetallic compounds, i.e. the target has been produced using a powder that contains an intermetallic compound. An example of such an intermetallic compound is Al₈Cr₅. This makes it possible, for example in a nitrogen-containing atmosphere, to produce an Al—Cr—N layer that essentially contains a composition of metallic components of 60 at % Al and 40 at % Cr. For example if a layer with a concentration ratio of 70 at % Al and 30 at % Cr is produced, then it is possible to use a target with the intermetallic compound Al₉Cr₄.

If other concentration ratios are to be produced, then according to another embodiment of the present invention, it is possible for arc vaporization to be carried out using a target produced by means of powder metallurgy in which the powder of one intermetallic compound has been mixed with the powder of another intermetallic compound. The atomic concentration of the metallic components then depends on the mixture ratio of the two powders.

According, to another embodiment, it is possible to use targets that contain the ceramic compounds AlN and CrN.

### DETAILED DESCRIPTION OF THE PREFERRED EMBODIMENTS

The present invention has disclosed the following:
A method for coating a substrate by means of cathodic arc vaporization in which a target produced by means of powder metallurgy is used as a material source for the arc vaporization and the powder used for producing the target contains a first intermetallic compound and a second intermetallic compound.
A method for coating a substrate by means of cathodic arc vaporization in which a target produced by means of powder metallurgy is used as a material source for the arc vaporization and the powder used for producing the target contains a first ceramic compound, preferably AlN, and a second ceramic compound, preferably CrN.
A method as described above in which the first ceramic compound is AlN.
A method as described above in which the second ceramic compound is AlN.

According to the present invention, in order to produce some layers, it can also be advantageous to use a method as described above, but in which the powder used for producing the target contains both an intermetallic compound and a ceramic compound.

1. A method for coating a substrate using cathodic arc vaporization, comprising:
using a target produced by powder metallurgy as a material source for the arc vaporization, wherein a powder used for producing the target contains a first intermetallic compound and a second intermetallic compound.

2. A method for coating a substrate using cathodic arc vaporization, comprising:
using a target produced by powder metallurgy as a material source for the arc vaporization, wherein a powder used for producing the target contains a first ceramic compound and a second ceramic compound.

3. The method according to claim 6, wherein the powder used for producing the target is the first ceramic compound AlN.

4. The method according to 7, wherein the powder used for producing the target is the second ceramic compound CrN.

5. The method according to claim 1, wherein the powder used for producing the target contains an intermetallic compound and a ceramic compound.

6. The method according to claim 2, wherein the first ceramic compound is AlN.

7. The method according to claim 2, wherein the second ceramic compound is CrN.

8. The method according to claim 2, wherein the powder used for producing the target contains an intermetallic compound and a ceramic compound.
